(19) United States
(12) Patent Application Publication
(10) Pub. No.: US 2026/0197957 A1
(43) Pub. Date: Jul. 9, 2026

(54) Unit Screen's Box Frame, Unit Screen, and Display

(71) Applicant: SHENZHEN GLOSHINE TECHNOLOGY CO., LTD., Shenzhen (CN)

(72) Inventors: Xianfeng Zhang, Shenzhen (CN); Guoqiang Li, Shenzhen (CN); Yongfeng Guo, Shenzhen (CN); Xinyong Chen, Shenzhen (CN)

(21) Appl. No.: 19/090,459

(22) Filed: Mar. 26, 2025

Related U.S. Application Data
(63) Continuation of application No. PCT/CN2025/070976, filed on Jan. 7, 2025.

(30) Foreign Application Priority Data
Jan. 3, 2025 (CN) 202520013465.4

(51) Int. Cl. H05K 5/30

(52) U.S. Cl. CPC H05K 5/30

(57) ABSTRACT

This application relates to the field of unit screen technology, particularly to a unit screen's box frame, unit screen, and display. The box frame includes a frame body including fixing parts and carbon fiber square tubes. The frame body is in a closed-loop shape with corners, each having a fixing part, a carbon fiber square tube is fixedly connected between adjacent fixing parts, which are suitable for fixing on a back of a display module; and the carbon fiber square tube is a hollow square tube with a first side surface, a second side surface, a third side surface, and a fourth side surface; the first is opposite and parallel to the third, and the second is opposite and parallel to the fourth; the first and second are perpendicularly connected or connected via a rounded corner, and the third and fourth are perpendicularly connected or connected via a rounded corner.

### CROSS REFERENCE TO RELATED APPLICATIONS

The present application is a Continuation Application of PCT Application No. PCT/CN2025/070976 filed on Jan. 7, 2025, which claims the benefit of Chinese Patent Application No. 202520013465.4 filed on Jan. 3, 2025. All the above are hereby incorporated by reference in their entirety.

### TECHNICAL FIELD

This application relates to the field of unit screen technology, particularly to a unit screen's box frame, unit screen, and display.

### BACKGROUND

Display screens are devices used to display text, images, videos, and other information. Large displays are usually composed of a plurality of unit screens, each including a box frame and a display module installed on the box frame. In use, all unit screens are typically transported to the site and then assembled into a complete display, which is then fixed to a steel structure for support.

However, existing box frames are heavy, requiring stronger steel structures for support, which limits the maximum size of the display module that can be installed. And the high labor intensity during hoisting makes it challenging for an individual operator to handle, thereby increasing installation difficulty and labor costs.

### SUMMARY OF THE INVENTION

The embodiments of the present application provide a unit screen's box frame, a unit screen, and a display, aiming to address the issue of excessive weight for the existing box frames.

In one aspect, the embodiments of the present application provide a unit screen's box frame, including a frame body, wherein the frame body includes a plurality of fixing parts and a plurality of carbon fiber square tubes, the frame body is in a closed-loop shape with a plurality of corners, each corner is provided with a fixing part, a carbon fiber square tube is fixedly connected between two adjacent fixing parts, the fixing part is suitable for fixing on a back of a display module of the unit screen; and
the carbon fiber square tube is a hollow square tube, an outer peripheral surface of the carbon fiber square tube includes a first side surface, a second side surface, a third side surface, and a fourth side surface; the first side surface is opposite and parallel to the third side surface, and the second side surface is opposite and parallel to the fourth side surface; the first side surface and second side surface are perpendicularly connected or connected via a rounded corner, and the third side surface and fourth side surface are perpendicularly connected or connected via a rounded corner.

Optionally, the first side surface and third side surface are rectangles of a same size, and the second side surface and fourth side surface are rectangles of a same size; the first side surface faces the back of the unit screen's display module, or the second side surface faces the back of the unit screen's display module; and
a width (A) of the first side surface is greater than a width (B) of the second side surface, and a range of B/A is 0.6-0.75.

Optionally, the second side surface of the carbon fiber square tube faces the back of the unit screen's display module.

Optionally, the first side surface and second side surface are connected via a first rounded corner, and the third side surface and fourth side surface are connected via a second rounded corner; and
the first rounded corner and the second rounded corner has an outer arc radius of R, the carbon fiber square tube has a wall thickness of t, and 2t<R<B/3.

Optionally, the fixing part is provided with two connecting ends, the two connecting ends are perpendicularly connected, a mounting hole is arranged in the connecting end, and the mounting hole has a cross-sectional shape matched with that of the carbon fiber square tube; and
an end of the carbon fiber square tube is inserted into the mounting hole of one fixing part, and another end is inserted into the mounting hole of another adjacent fixing part.

Optionally, the frame body is square, the carbon fiber square tubes are provided in a quantity of four, and the fixing parts are provided in a quantity of four; two of the carbon fiber square tubes extend in a first direction, and another two carbon fiber square tubes extend in a second direction; and the first direction is perpendicular to the second direction; and
the unit screen's box frame also includes a main beam extending along the second direction, both ends of the main beam have guide holes extending along the first direction, the carbon fiber square tubes extending along the first direction pass through the corresponding guide holes, and the guide hole has a cross-sectional shape matched with that of the carbon fiber square tube.

Optionally, the unit screen's box frame further includes a connection lock and a locking part, wherein the connection lock is installed on the fixing part on a side of the frame body along the first direction, and the locking part is installed on the fixing part on another side of the frame body along the first direction; and
wherein the connection lock of one unit screen's box frame is used to lock with the locking part of another adjacent unit screen's box frame, allowing temporary fixation between the two unit screens.

Optionally, the unit screen's box frame further includes a first positioning bracket and a second positioning bracket, wherein the first positioning bracket is provided with a first through-hole penetrating along the second direction, and the second positioning bracket is provided with a second through-hole penetrating along the second direction; the first through-hole and the second through-hole have cross-sectional shapes adapted to match with that of the carbon fiber square tube;
the carbon fiber square tube extending along the second direction and near the first positioning bracket passes through the first through-hole, and the carbon fiber square tube extending along the second direction and near the second positioning bracket passes through the second through-hole; and
the first positioning bracket is provided with a positioning protrusion protruding toward a side away from the second positioning bracket, the second positioning bracket is provided with a positioning groove, and the positioning groove has an opening facing away from the first positioning bracket; the positioning protrusion of the box frame of one unit screen is configured to engage with the positioning groove of the second positioning bracket of the box frame of another adjacent unit screen.

In another aspect, the embodiments of the present application provide a unit screen, including a display module and the unit screen's box frame described above, wherein the fixing part is fixed on a back of the display module.

In another aspect, the embodiments of the present application provide a display, wherein the display is assembled from a plurality of the unit screens described above.

According to the unit screen's box frame of the present application, a carbon fiber square tube is connected between two adjacent fixing parts of the frame body, enabling the frame body to form into a closed-loop structure. Because the carbon fiber square tube is made of carbon fiber material, it is lightweight and high-strength. This ensures the overall high strength of the box frame while reducing its total weight, thereby decreasing the weight of the unit screen. This reduction in weight minimizes the impact of the box frame on the installation limits of the display module, reduces the labor intensity required for hoisting, and lowers the difficulty of installation. Furthermore, the square-shaped carbon fiber square tube provides a larger load-bearing area and higher load-bearing capacity, enabling the box frame to support larger-sized display modules.

### BRIEF DESCRIPTION OF THE DRAWINGS

To clearly illustrate the technical solutions of the embodiments of this application, the following briefly introduces the accompanying drawings used in the description of the embodiments. Obviously, the drawings in the following description are only some embodiments of this application. For those skilled in the art, other drawings can be obtained based on these drawings without creative effort.

FIG. 1 is a structural schematic diagram of the unit screen according to an embodiment of the present application.

FIG. 2 is a structural schematic diagram of the carbon fiber square tube shown in FIG. 1.

FIG. 3 is a cross-sectional schematic diagram of the carbon fiber square tube shown in FIG. 2.

Reference signs in the drawings are as follow:
10l . Frame body; 200. Display module;
1. Carbon fiber square tube; 11. First side surface; 12. Second side surface; 2. Fixing part; 21. Connecting end; 22. Connecting post; 23. First positioning seat; 24. Second positioning seat; 3. Main beam; 31. Handle; 4. Connection lock; 5. Locking part; 6. First positioning bracket; 7. Second positioning bracket; 71. Positioning groove; 8. Power module.

### DETAILED DESCRIPTION OF DISCLOSED EMBODIMENTS

To make the technical problems, technical solutions and beneficial effects of the present application more clear, the application will be further explained in detail below with reference to the drawings and embodiments. It should be understood that the specific embodiments described here are only used to illustrate the application, rather than to limit the application.

In the description of the present application, it is to be understood that the terms “longitudinal”, “radial”, “length”, “width”, “thickness”, “upper”, “lower”, “front”, “rear”, “left”, “right”, “vertical”, “horizontal”, “top”, “bottom”, “inner”, “outer”, and the like indicate an orientation or positional relationship based on that shown in the drawings. They are only for convenience of description and simplicity of description only, not intended to indicate or imply that the indicated devices or elements must have a particular orientation, be constructed and operated in a particular orientation, and are therefore not to be construed as limiting the present application. In the description of this application, unless otherwise specified, “a plurality of” means two or more.

In the description of this application, it should be noted that unless otherwise specified and limited, the terms “install,” “connect,” and “link” should be understood broadly. For example, they may be fixed connections, detachable connections, or integral connections; they may be mechanical connections or electrical connections; they may be direct connections or indirect connections through an intermediate medium, or internal communication of two elements. For those skilled in the art, the specific meanings of the above terms in this application can be understood according to specific situations.

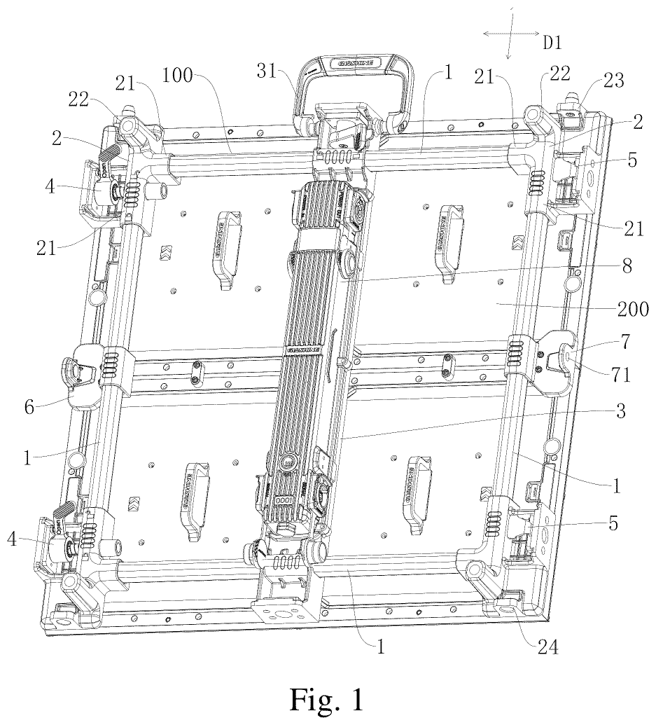

As shown in FIGS. 1 to 3, an embodiment of this application provides a unit screen, including a display module 200 and a unit screen's box frame. The unit screen's box frame includes a frame body 100, wherein the frame body 100 includes a plurality of fixing parts 2 and a plurality of carbon fiber square tubes 1, the frame body 100 is in a closed-loop shape with a plurality of corners, each corner is provided with a fixing part 2, a carbon fiber square tube 1 is fixedly connected between two adjacent fixing parts 2, the fixing part 2 is suitable for fixing on a back of a display module 200 of the unit screen.

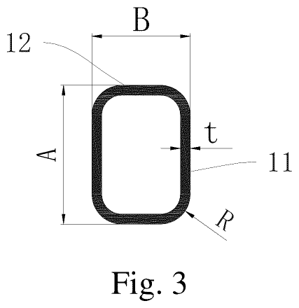

As shown in FIG. 3, the carbon fiber square tube 1 is a hollow square tube, an outer peripheral surface of the carbon fiber square tube 1 includes a first side surface 11, a second side surface 12, a third side surface, and a fourth side surface; the first side surface 11 is opposite and parallel to the third side surface, and the second side surface 12 is opposite and parallel to the fourth side surface; the first side surface 11 and second side surface 12 are perpendicularly connected or connected via a rounded corner, and the third side surface 11 and fourth side surface 12 are perpendicularly connected or connected via a rounded corner.

Because the carbon fiber square tube 1 is made of carbon fiber material, it is lightweight and high-strength, ensuring the overall strength of the box frame while reducing its weight. This reduces the weight of the unit screen, minimizes the impact on the installation limits of the display module 200, reduces hoisting labor intensity, and lowers installation difficulty. Additionally, the square carbon fiber square tube 1 has a larger load-bearing area and higher load-bearing capacity, enabling the box frame to support larger display modules 200.

In one embodiment, the first side surface 11 and third side surface are rectangles of a same size, and the second side surface 12 and fourth side surface are rectangles of a same size; the first side surface 11 faces the back of the unit screen's display module 200, or the second side surface 12 faces the back of the unit screen's display module 200.

A width A of the first side surface 11 is greater than a width B of the second side surface 12, and a range of B/A is 0.6-0.75. The length of the first side surface 11 and the length of the second side surface 12 are the dimensions of the carbon fiber square tube 1 in its extending direction.

For the carbon fiber square tube 1, the closer B/A is to 1, the greater the weight and volume per unit length of the carbon fiber square tube 1, the larger the load-bearing area, and the more space it occupies. The smaller B/A is, the smaller the load-bearing area per unit length of the carbon fiber square tube 1 and the less space it occupies. Therefore, in this application, the B/A ratio of the carbon fiber square tube 1 is designed to be in the range of 0.6 to 0.75, ensuring that the box frame has the advantages of being lightweight and having a high load-bearing capacity.

In one embodiment, as shown in FIGS. 1 and 3, the second side surface 12 of the carbon fiber square tube 1 faces the back of the unit screen's display module 200. The second side surface 12 bears the force transmitted from the display module 200 to the carbon fiber square tube 1 through the fixing part 2. Since the width (B) of the second side surface 12 is smaller than the width (A) of the first side surface 11, the area of the second side surface 12 is relatively smaller. Under the same force, the carbon fiber square tube 1 has higher bending strength and better load-bearing performance.

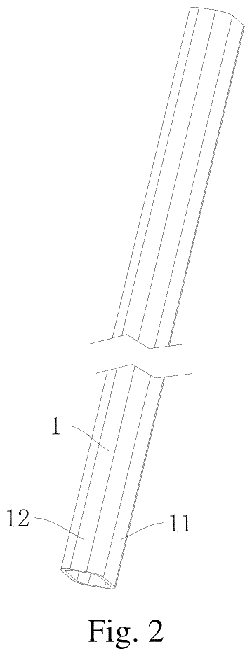

In one embodiment, as shown in FIGS. 2 and 3, the first side surface 11 and second side surface 12 are connected via a first rounded corner, and the third side surface and fourth side surface are connected via a second rounded corner; and the first rounded corner and the second rounded corner has an outer arc radius of R, the carbon fiber square tube 1 has a wall thickness of t, and 2t<R<B/ 3.

The adjacent walls of the carbon fiber square tube 1 are connected via rounded corners to avoid stress concentration and improve the structural strength of the carbon fiber square tube 1.

In one embodiment, A=21, B=15, t=1.5, R=4.5.

Certainly, in actual design, the dimensions of the carbon fiber square tube 1 (A, B, t, R) can be adjusted according to load-bearing and installation space requirements. Preferably, the dimensions of A, B, t, and R should ensure that B/A is within the range of 0.6 to 0.75, and 2t<R<B/3. For example, B/A can be 0.6, 0.65, 0.7, or 0.75. Certainly, B/A can also be 0.5, 0.55, 0.8, or 0.9, or A=B, or B>A. The dimensions of t and R can also be R≤2t or R≥B/3.

In other embodiments, the first side surface 11 of the carbon fiber square tube 1 may face the back of the display module 200 of the unit screen.

In one embodiment, as shown in FIG. 1, the fixing part 2 is provided with two connecting ends 21, the two connecting ends 21 are perpendicularly connected, a mounting hole is arranged in the connecting end 21, and the mounting hole has a cross-sectional shape matched with that of the carbon fiber square tube 1.

an end of the carbon fiber square tube 1 is inserted into the mounting hole of one fixing part 2, and another end is inserted into the mounting hole of another adjacent fixing part 2.

The box frame is a modular structure. When transporting the box frame, all its components are transported to the installation site, and the box frame is assembled on-site. Specifically, the two ends of the carbon fiber square tube 1 are inserted into the mounting holes of the connecting ends 21 of two adjacent fixing parts 2, respectively, so as to be assembled into a closed frame body 100. Then, the fixing part 2 is fixed to the back of the display module 200.

Since the outer contour of the carbon fiber square tube 1 is square, when the carbon fiber square tube 1 is inserted into the mounting hole, the mounting hole and the carbon fiber square tube 1 can guide each other, so as to position the carbon fiber square tube 1 and prevent it from rolling or misaligning. Moreover, the carbon fiber square tube 1 and fixing part 2 are assembled by insertion, which simplifies the assembly process and improves installation efficiency.

In one embodiment, the carbon fiber square tube 1 is bonded to the fixing part 2, making installation easier and ensuring a firm connection that is less likely to loosen.

In one embodiment, as shown in FIG. 1, the frame body 100 is square, the carbon fiber square tubes 1 are provided in a quantity of four, and the fixing parts 2 are provided in a quantity of four; two of the carbon fiber square tubes 1 extend in a first direction, and another two carbon fiber square tubes 1 extend in a second direction; and the first direction is perpendicular to the second direction. In FIG. 1, D1 represents the first direction, and D2 represents the second direction.

The unit screen's box frame also includes a main beam 3 extending along the second direction, both ends of the main beam 3 have guide holes extending along the first direction, the carbon fiber square tubes 1 extending along the first direction pass through the corresponding guide holes, and the guide hole has a cross-sectional shape matched with that of the carbon fiber square tube 1.

The main beam 3 is connected between the carbon fiber square tubes 1 on opposite sides of the frame body 100 along the second direction, enhancing the structural strength of the box frame and allowing it to support heavier display modules 200.

In other embodiments, the frame body 100 can be triangular, rhombus-shaped, hexagonal, etc.

In one embodiment, as shown in FIG. 1, the unit screen also includes a power module 8, which is installed on the main beam 3. This allows the power module 8 to be installed using the existing structural components of the box frame, eliminating the need for additional installation parts and simplifying the structure of the box frame.

In one embodiment, the unit screen also includes a connection lock 4 and a locking part 5. The connection lock 4 is installed on the fixing part 2 on one side of the frame body 100 along the first direction, and the locking part 5 is installed on the fixing part 2 on the other side of the frame body 100 along the first direction.

The connection lock 4 of one unit screen's box frame is used to lock with the locking part 5 of another adjacent unit screen's box frame, allowing temporary fixation between the two unit screens. This enables a plurality of unit screens to be assembled into the desired display. When disassembling the display, the connection lock 4 of one unit screen is detached from the locking part 5 of the adjacent unit screen, separating the two unit screens, making disassembly and assembly convenient.

Moreover, the connection lock 4 and locking part 5 are installed on the fixing parts 2 at the corners of the frame body 100, ensuring that two ends of the adjacent carbon fiber square tubes 1 of two adjacent box frames are securely locked, making the connection more robust.

In one embodiment, the upper end of the main beam 3 is provided with a handle 31, making it easier to transport the unit screen.

In one embodiment, as shown in FIG. 1, the unit screen also includes a first positioning bracket 6 and a second positioning bracket 7, wherein the first positioning bracket 6 is provided with a first through-hole penetrating along the second direction, and the second positioning bracket 7 is provided with a second through-hole penetrating along the second direction. The cross-sectional shapes of the first and second through-holes are adapted to match the cross-sectional shape of the carbon fiber square tube 1.

The carbon fiber square tube 1 extending along the second direction and near the first positioning bracket 6 passes through the first through-hole, and the carbon fiber square tube 1 extending along the second direction and near the second positioning bracket 7 passes through the second through-hole. This prevents damage to the structure of the carbon fiber square tube 1.

The first positioning bracket 6 is provided with a positioning protrusion protruding toward a side away from the second positioning bracket 7, the second positioning bracket 7 is provided with a positioning groove 71, and the positioning groove 71 has an opening facing away from the first positioning bracket 6; the positioning protrusion of the box frame of one unit screen is configured to engage with the positioning groove 71 of the second positioning bracket 7 of the box frame of another adjacent unit screen.

When assembling two adjacent unit screens, the positioning protrusion on the first positioning bracket 6 of one unit screen is first inserted into the positioning groove 71 on the second positioning bracket 7 of the adjacent unit screen. Then, the connection lock 4 of the unit screen is locked with the locking part of the adjacent unit screen.

The engagement of the positioning protrusion and the positioning groove 71 can preliminarily position the two adjacent unit screens, improving the positioning accuracy of the adjacent unit screens, facilitating the subsequent connection and fixation of the two unit screens, reducing installation difficulty, and ensuring a more stable connection between the two unit screens.

In one embodiment, as shown in FIG. 1, the fixing part 2 also includes a connecting post 22, which is arranged on a side of the fixing part 2 facing away from the display module 200. The connecting post 22 is provided with a connecting hole, which is used to connect to the steel structure at the installation location of the display, fixing the unit screen at the desired installation position.

In one embodiment, the two fixing parts 2 on one side of the frame body 100 along the second direction are provided with first positioning seats 23, and the two fixing parts 2 on the other side of the frame body 100 along the second direction are provided with second positioning seats 24. The first positioning seat 23 is provided with a positioning pin extending away from the first positioning seat 23, the second positioning seat 24 is provided with a positioning hole, and the positioning hole has an opening facing away from the first positioning seat 23. When a plurality of unit screens are assembled along the second direction, the positioning pin on one unit screen is inserted into the positioning hole of another adjacent unit screen.

In one embodiment, the first direction is the left-right direction. The two fixing parts 2 on the left side of the frame body 100 are both provided with connection locks 4, and the two fixing parts 2 on the right side of the frame body 100 are both provided with locking parts 5. When two unit screens are assembled along the left-right direction, the connection lock 4 of one unit screen is locked with the locking part 5 of the other unit screen.

In other embodiments, the fixing part 2 and the carbon fiber square tube 1 can be fixed by welding or by flange connection.

In other embodiments, the connection lock 4 and locking part 5 can be fixed on the carbon fiber square tube 1.

Furthermore, an embodiment of this application provides a box frame for a unit screen, the structure of which is the same as that of the unit screen's box frame described in any of the above embodiments, and thus will not be repeated here.

Furthermore, an embodiment of this application provides a display, which is assembled from a plurality of unit screens described in any of the above embodiments.

The above embodiments are only used to illustrate the technical solutions of this application, but not to limit it. Although the application has been described in detail with reference to the aforementioned embodiments, those of ordinary skill in the art should understand that the technical solutions described in the aforementioned embodiments may still be modified, or some of the technical features may be equivalently replaced. However, these modifications or substitutions do not make the essence of the technical solutions deviate from the spirit and scope of the technical solutions of each embodiment of this application, and shall be included in the protection scope of this application.

What is claimed is:

1. A unit screen's box frame, comprising a frame body, wherein the frame body comprises a plurality of fixing parts and a plurality of carbon fiber square tubes, the frame body is in a closed-loop shape with a plurality of corners, each corner is provided with a fixing part, a carbon fiber square tube is fixedly connected between two adjacent fixing parts, the fixing part is suitable for fixing on a back of a display module of the unit screen; and
the carbon fiber square tube is a hollow square tube, an outer peripheral surface of the carbon fiber square tube comprises a first side surface, a second side surface, a third side surface, and a fourth side surface; the first side surface is opposite and parallel to the third side surface, and the second side surface is opposite and parallel to the fourth side surface; the first side surface and second side surface are perpendicularly connected or connected via a rounded corner, and the third side surface and fourth side surface are perpendicularly connected or connected via a rounded corner.

2. The unit screen's box frame of claim 1, wherein the first side surface and third side surface are rectangles of a same size, and the second side surface and fourth side surface are rectangles of a same size; the first side surface faces the back of the unit screen's display module, or the second side surface faces the back of the unit screen's display module; and
a width (A) of the first side surface is greater than a width (B) of the second side surface, and a range of B/A is 0.6-0.75.

3. The unit screen's box frame of claim 2, wherein the second side surface of the carbon fiber square tube faces the back of the unit screen's display module.

4. The unit screen's box frame of claim 2, wherein the first side surface and second side surface are connected via a first rounded corner, and the third side surface and fourth side surface are connected via a second rounded corner; and
the first rounded corner and the second rounded corner has an outer arc radius of R, the carbon fiber square tube has a wall thickness of t, and 2t<R<B/3.

5. The unit screen's box frame of claim 1, wherein the fixing part is provided with two connecting ends, the two connecting ends are perpendicularly connected, a mounting hole is arranged in the connecting end, and the mounting hole has a cross-sectional shape matched with that of the carbon fiber square tube; and
an end of the carbon fiber square tube is inserted into the mounting hole of one fixing part, and another end is inserted into the mounting hole of another adjacent fixing part.

6. The unit screen's box frame of claim 1, wherein the frame body is square, the carbon fiber square tubes are provided in a quantity of four, and the fixing parts are provided in a quantity of four; two of the carbon fiber square tubes extend in a first direction, and another two carbon fiber square tubes extend in a second direction; and the first direction is perpendicular to the second direction; and
the unit screen's box frame also comprises a main beam extending along the second direction, both ends of the main beam have guide holes extending along the first direction, the carbon fiber square tubes extending along the first direction pass through the corresponding guide holes, and the guide hole has a cross-sectional shape matched with that of the carbon fiber square tube.

7. The unit screen's box frame of claim 6, further comprising a connection lock and a locking part, wherein the connection lock is installed on the fixing part on a side of the frame body along the first direction, and the locking part is installed on the fixing part on another side of the frame body along the first direction; and
wherein the connection lock of one unit screen's box frame is used to lock with the locking part of another adjacent unit screen's box frame, allowing temporary fixation between the two unit screens.

8. The unit screen's box frame of claim 7, further comprising a first positioning bracket and a second positioning bracket, wherein the first positioning bracket is provided with a first through-hole penetrating along the second direction, and the second positioning bracket is provided with a second through-hole penetrating along the second direction; the first through-hole and the second through-hole have cross-sectional shapes adapted to match with that of the carbon fiber square tube;
the carbon fiber square tube extending along the second direction and near the first positioning bracket passes through the first through-hole, and the carbon fiber square tube extending along the second direction and near the second positioning bracket passes through the second through-hole; and
the first positioning bracket is provided with a positioning protrusion protruding toward a side away from the second positioning bracket, the second positioning bracket is provided with a positioning groove, and the positioning groove has an opening facing away from the first positioning bracket; the positioning protrusion of the box frame of one unit screen is configured to engage with the positioning groove of the second positioning bracket of the box frame of another adjacent unit screen.

9. A unit screen, comprising a display module and the unit screen's box frame of claim 1, wherein the fixing part is fixed on a back of the display module.

10. A display, characterized in that the display is assembled from a plurality of the unit screens of claim 9.
